(19) United States
(12) Patent Application Publication
(10) Pub. No.: US 2003/0081596 A1
(43) Pub. Date: May 1, 2003

(54) Intelligent optical network linecard with localized processing functionality

(76) Inventors: John Kikidis, Patras (GR); Vagelis Mariatos, Patras (GR); Kostas Adaos, Amaliada (GR); Finn Leif Kraemer, Nacrum (DK)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/165,013

(22) Filed: Jun. 6, 2002

Related U.S. Application Data
(60) Provisional application No. 60/297,205, filed on Jun. 6, 2001.

(51) Int. Cl. H04L 12/66; H03M 13/03

(52) U.S. Cl. 370/356

(57) ABSTRACT

A device is provided comprising an intelligent optical network linecard. An intelligent optical linecard can utilize localized processing that facilitates scaling, enables switching in the optical domain, promotes management of dissimilar networks, provides the ability for bandwidth allocation on demand and in general can interface and utilize optical control plane signaling to dynamically control linecard functions.

This application claims the benefit of U.S. Provisional Application No. 60/297,205, filed Jun. 6, 2001.

### TECHNICAL FIELD

The invention relates generally to an intelligent optical network linecard and, more particularly, to a linecard with localized processing that facilitates scaling, enables switching in the optical domain, promotes management of dissimilar networks, provides the ability for bandwidth allocation on demand and in general can interface and utilize optical control plane signaling to dynamically control linecard functions.

### BACKGROUND

There has been significant research and developments in recent years with optical networks and optical network elements. For instance advancements in Wavelength Division Multiplexing (“WDM”) and Dense WDM (“DWDM”) have dramatically increased the amount of information that the fiber infrastructure can carry. Advancements in fiber bandwidth have subsequently necessitated advancements in the equipment at the end of each fiber in order to deal with the greater bandwidth. Therefore the hardware that was designed to support the previous bandwidth levels on fiber is now insufficient.

Another advancement is the development of new protocols to operate the fiber backbone. Different optical transport protocols such as Synchronous Optical Network (“SONET”) and Synchronous Design Hierarchy (“SDH”) control different networks, and are presumptively going to be channeled over a unifying protocol such as the recently introduced Optical Transport Network (OTN), sometimes called a third generation optical network. Encapsulating one protocol into another requires processing in order to preserve the original protocol's control information, for instance for routing or error correction, as well as the actual data, or payload, information. The encapsulation processing that happens in the data plane is called “digital wrapping” or “mapping.”

Multiple protocols allowed fiber optics signaling in different networks but as the fiber backbone continues to develop new protocols are being developed that will ideally unify fiber optic technology under one workable system. Advancements in fiber technology allowed longer fibers to be used, which in turn created the need to provision channels at nodes in order to connect two distant points. Provisioning became a requirement but did not keep up with the advances in dynamically configurable routes such as those used in TCP/IP networks.

### BRIEF DESCRIPTION OF THE DRAWINGS

The present invention is illustrated by way of example, and not necessarily by way of limitation in the figures of the accompanying drawings in which like reference numerals refer to similar elements.

FIG. 1 is an illustration of one embodiment of the present invention.

FIG. 2 is an illustration of another embodiment of the present invention utilizing a generic computing system.

### DETAILED DESCRIPTION

An apparatus for an intelligent optical network linecard with localized processing functionality is disclosed. In the following description numerous specific details are set forth in order to provide a thorough understanding of the present invention. It will be apparent, however, to one having ordinary skill in the art that the specific detail need not be employed to practice the present invention. In other instances, well known materials or methods have not been described in detail in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification do not necessarily all refer to the same embodiment.

The increasing speed and complexity of the fiber optic network significantly impacts the performance requirements of fiber optic networking equipment. Wavelength Division Multiplexing (WDM) and Dense Wavelength Division Multiplexing (DWDM) substantially increase the bandwidth of optical fibers. Much of the fiber optic backbone of the communication system utilizes either a WDM or DWDM scheme. To support this increase in bandwidth in the fiber, substantial improvements, such as processing capabilities located on the linecard, in the optic equipment connected to the fiber are required. One of these requirements is the addition of more linecards per fiber. With either WDM or DWDM, many more signals are passed through the fiber lines. Each of these new signals currently requires a new linecard. The addition of extra linecards per each fiber supports increases in bandwidth, however their addition generates scaling complications. Manageability and provisioning of the network is complicated substantially by the substantial increase in equipment.

In current fiber optic networks, provisioning was accomplished manually. Each linecard would be added, configured, and provisioned by a person installing or setting the linecard. Manual provisioning of linecards is a time consuming and often error prone process. Furthermore, once a channel (circuit) was established, it would stay that way until manually re-provisioned. In an increasingly complex optical network, this becomes a considerable scaling issue as the network can not respond to changes as well as desired.

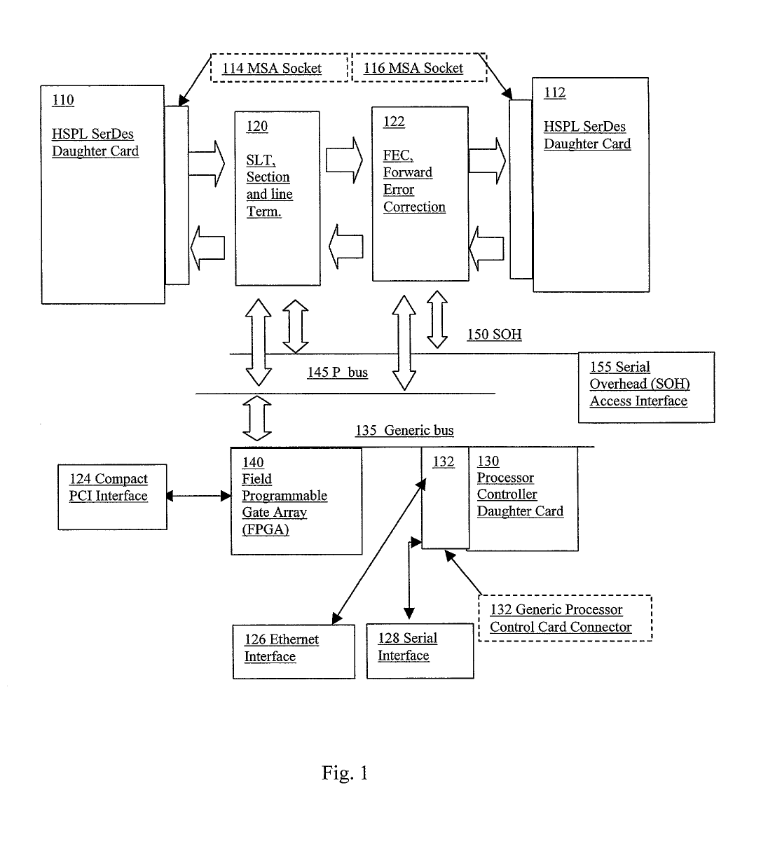

The addition of a processor, of any variety, on the linecard allows for automatic provisioning. Furthermore, the addition of a processor to the linecard allows for greater scalability, upgradability, data forwarding capability, and signaling as well as any tasks that would be more efficiently handled on the linecard as opposed to done remotely or manually. In reference to FIG. 1, the elements above bus 145 are data plane elements and the elements below it are control plane elements. The data plane is sometimes called the “user plane” or the “transport plane” and is used to transport data, voice, video, or other content traffic. The control plane has been described as software and/or hardware in a node that is used to control operations of the network such as allocating bandwidth, error recovery, route discovery etc.

FIG. 1 illustrates an embodiment that includes a Field Programmable Gate Array (FPGA) 140, a generic bus 135, a Processor bus 145, a generic Processor control card connector 132, a processor controller daughter card 130, section and line termination equipment (SLT) 120, Forward Error Correction (FEC) equipment 122, a serializer/deserializer (SerDes) high speed physical layer (HSPL) daughter card 110, a serializer/deserializer (SerDes) high speed physical layer (HSPL) daughter card 112, as well as interfacing equipment for Peripheral Component Interconnect (PCI), Ethernet and Serial lines 124, 126 and 128, respectively.

The SerDes cards need not be HSPL SerDes cards but can be any of numerous SerDes solutions now known or offered subsequently. The interfacing lines in this embodiment need not be restricted to PCI, Ethernet and Serial lines but may be any interface to transmit data now known or later developed. Furthermore, the FPGA 140 need not be restricted as a FPGA. Any processing device, programmable or not, would satisfy other embodiments of the present invention. Microprocessors, programmable logic devices, network processors, Application Specific Integrated Circuits (ASICs), Digital Signal Processors (DSPs), chipsets, and any other processing device would satisfy as the processing portion of an embodiment of the present invention. Furthermore FEC equipment 122, can be other types of error correction integrated circuits and need not be restricted by FEC solutions.

The processing device 140 is connected to a processor bus 145. The processing device 140 can also be coupled to a processor controller daughter card 130, through a generic microprocessor bus 135 and a generic processor control card 132. The FPGA 140, or other processing device, can also be connected to a compact PCI, PCI, non-PCI or other type of interface.

In this embodiment the FPGA 140, or other processing device, receives control plane or data plane signals through the bus 145. In this embodiment, either the FPGA 140, or other processing device, or the processor controller daughter card 130 may have the processing power to enable full Operation, Administration, Maintenance, and Provisioning (OAM&P). Distributed control management, over an optical network is possible by utilizing this local microprocessor processing capability. The generic microprocessor bus interface 135, along with the FPGA 140, makes it possible to interface and enable control from any type of processor.

In the present embodiment, the FPGA 140, or other processing device, provides a flexible control plane design by allowing adjustable addressing schemes and by acting as a bridge device. All control lines between the processor controller card 130, and the SLT 120 and FEC 122 and the compact PCI bus or other type interface 124 are routed through the FPGA 140. By connecting the FPGA 140, or other processing device, with the Section and Line Termination integrated circuit 120 or with the Forward Error Correction 122 integrated circuit the processor can process, at the linecard level, based upon error correction or line termination information.

In this embodiment, the FPGA 140, or other processing device, also implements the bus 135 that interfaces to the generic processor control card connector 132, on which the processor control card for the systems local processing needs is hosted. The FPGA 140, or other processing device, furthermore allows high level management functions of the system to be performed by an application processor interfacing through a compact PCI, PCI, or other interface back plane. In one embodiment the linecard could be functioning as a single slave device on PCI bus connected through the compact PCI Interface 124. This allows either local processing capability or remote management of the linecard.

In the embodiment in FIG. 1, external overhead processing for both the SLT 120 and the FEC 122 is possible by interfacing a relevant external (such as HDLC, Codec, FPGA) card to the headers provided on the motherboard. This allows any kind of add drop overhead operations or processing to be possible.

The embodiment of FIG. 1 enables either distributed or centralized control through the use of the FPGA 140 and connecting buses. Distributed control is enabled by using the local processing capability, for instance a FPGA 140, while centralized control is allowed through the Compact PCI Interface 124, giving direct control and access to the SLT 120 and FEC 122.

The embodiment in FIG. 1 enables overhead (OH) processing functionality local at the linecard. Many fiber optic networks are switched without access to overhead. In order to more effectively switch optical signals, information regarding the signal must reach a cross connect, a switching device (XC) before the optical signals actually reaches the XC. This need can be solved by sending the OH out of band (OOB), or in a different signal than the actual payload. To more effectively switch in the optical domain, access to OH is required, which is in turn provided by OH processing capability local to the linecard.

Current optical networking protocols such as SONET, SDH, and OTN use overhead in optical envelopes to, at least in part, act as a pointer to the actual payload portion of the envelope (“framing”). This allows for more robustness in timing. Overhead information can also include other information, for instance in a SONET environment, the data communications channel (DCC) portion of OH is used for signaling control, administrative alarms, other OAM&P, and can even be used for multi protocol label switching (MPLS). When SONET is encapsulated into OTN, it wrapped in its entirety and the resulting encapsulation is sent over OTN. A benefit of having a processor at the linecard level is to extract OH information, such as the DCC bytefield of SONET and then transport the encapsulation as OTN but in the OTN OH still utilize the information from the DCC bytefield, for instance, mapped into the general communication channel (GCC) of OTN.

OH processing functionality at the linecard also benefits switching in the optical domain in addition to management of dissimilar networks. By having the ability to process different portions of the OH that the linecard is relaying, choices can be made regarding the overhead, such as routing, that is directly determined by the information in the OH.

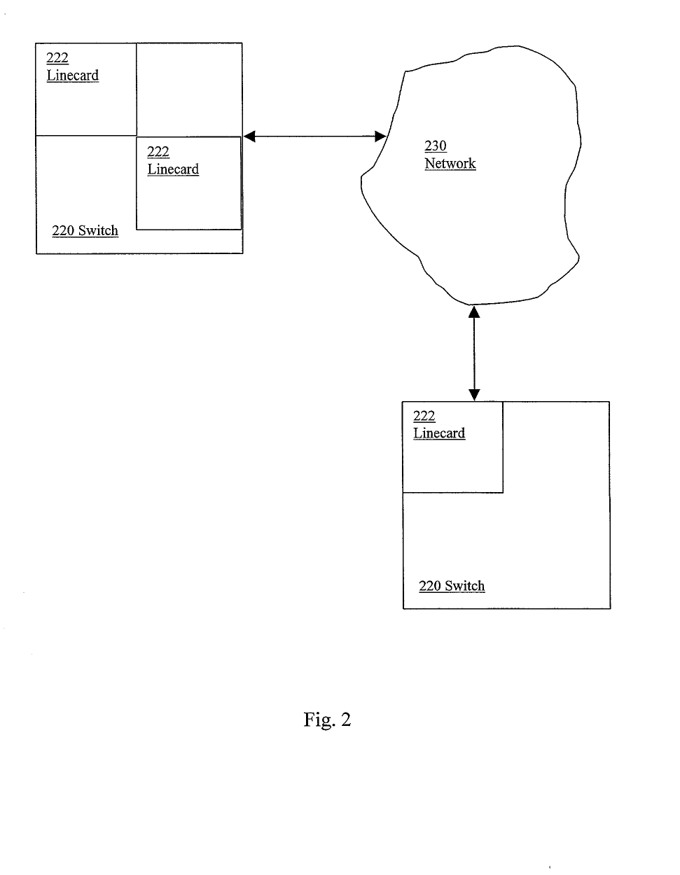

FIG. 2 illustrates an embodiment of the invention in a system. Referring to FIG. 2, one embodiment may be any node 220 or combination of nodes in an optical network 230, or any other computing system that processes signals originating from an optical fiber. The system illustrated in FIG. 2 is intended to represent a range of optical systems. Alternative optical systems can include more, fewer and/or different components.

Processing functionality local to the linecard allows a distributed intelligence through an optical network by control through a backplane, such as PCI interface 124, or other interface, or by extraction of OH from the optical line. A switch 220 including a linecard 222 comprising one embodiment of the present invention can be connected through a network 230 to a switch 220 including a linecard 222 comprising one embodiment of the present invention. The embodiment of FIG. 2 enables either distributed or centralized control through the use of the FPGA 140 and connecting buses. Distributed control is enabled by using the local processing capability, for instance a FPGA 140, while centralized control is allowed through the Compact PCI Interface 124, giving direct control and access to the SLT 120 and FEC 122. With processing functionality on each linecard, each linecard can in turn allow dynamic provisioning, furthermore each linecard can handle data plane tasks more effectively such as encapsulation and error correction by being coupled with the SLT 120 and FEC 122.

Furthermore, the embodiment in FIG. 2 enables switching in the optical domain. The Serial Overhead Interface (SOH) 155 is connected to the FPGA 140, or other processor, the Processor Daughter Card 130, and also to the SLT 120 and FEC 122. By having access to the OH information each node in a network can forward to other nodes intelligently by using local processing capabilities to make decisions based upon the OH information.

As mentioned above, in this embodiment, the FPGA 140, or other processing device, also implements the bus 135 that interfaces to the generic processor control card connector 132, on which the processor control card for the systems local processing needs is hosted. The FPGA 140, or other processing device, furthermore allows high level management functions of the system to be performed by an application processor interfacing through a compact PCI, PCI, or other interface back plane. In one embodiment the linecard could be functioning as a single slave device on PCI bus connected through the compact PCI Interface 124. This allows either local processing capability or remote management of the linecard.

In the embodiment in FIG. 2, external overhead processing for both the SLT 120 and the FEC 122 is possible by interfacing a relevant external (such as HDLC, Codec, FPGA) card to the headers provided on the motherboard. This allows any kind of add drop overhead operations or processing to be possible.

Therefore processing locally to the linecard allows a distributed intelligence through an optical network by control through a backplane, such as PCI interface 124, or other interface, or by extraction of OH from the optical line. A switch 220 including a linecard 222 comprising one embodiment of the present invention can be connected through a network 230 to a switch 220 including a linecard 222 comprising one embodiment of the present invention.

In the foregoing detailed description, the method and apparatus of the present invention have been described with reference to specific exemplary embodiments thereof. It will, however, be evident that various modifications and changes may be made thereto without departing from the broader spirit and scope of the present invention. The present specification and figures are accordingly to be regarded as illustrative rather than restrictive.

1. An apparatus comprising:
a line input port to receive a signal;
a line output port to send a signal;
a linecard coupled with the input and output ports; and
at least one processing device coupled with the input and output ports to perform at least one of digital wrapping and signal mapping of signals on the linecard.

2. The apparatus of claim 1 wherein the processing device is a Field Programmable Gate Array (FPGA).

3. The apparatus of claim 1 wherein the processing device is a network processor.

4. The linecard of claim 1 further comprising an error correction integrated circuit coupled to at least one of the input port, the output port, and the processing device.

5. The linecard of claim 4 wherein the error correction integrated circuit is a Forward Error Correction (FEC) integrated circuit.

6. The linecard of claim 4 wherein the error correction integrated circuit is a Digital Wrapper (WRAP) integrated circuit.

7. An apparatus comprising:
a line input port to receive a signal;
a line output port to send a signal:
a linecard coupled with the input and output ports; and
at least one control plane processing device coupled with the input and output ports to enable control plane processing functionality on the linecard.

8. The apparatus of claim 7 wherein the control plane processing device is a Field Programmable Gate Array (FPGA).

9. The apparatus of claim 7 wherein the control plane processing device is a network processor.

10. The linecard of claim 7 further comprising an error correction integrated circuit.

11. The linecard of claim 10 wherein the error correction integrated circuit is a Forward Error Correction (FEC) integrated circuit.

12. The linecard of claim 10 wherein the error correction integrated circuit is a Digital Wrapper (WRAP) integrated circuit.

13. An apparatus comprising:
a input port to receive at least one of optical and electrical signals;
a output port to send at least one of optical and electrical signals;
a linecard coupled with the input and output ports; and
a processor on the linecard to enable processing local to the line card.

14. The apparatus of claim 13 wherein the processor is a Field Programmable Gate Array (FPGA).

15. The apparatus of claim 13 wherein the processor is a network processor.

16. The linecard of claim 13 further comprising at least one of an error correction integrated circuit and a digital wrapper integrated circuit.

17. The linecard of claim 16 wherein the error correction integrated circuit is a Forward Error Correction (FEC) integrated circuit.

18. An optical networking linecard comprising:
input and output (I/O) ports for receiving and sending information;
a motherboard coupled with the I/O ports; and
a processor coupled to the linecard to select linecard settings.

19. The processor of claim 18 wherein the linecard settings include at least one of organization, administration, maintenance and provisioning.

20. The processor of claim 18 wherein the linecard settings include bandwidth allocation.

21. The processor of claim 18 wherein the linecard settings are determined by control plane signals.

22. The linecard of claim 18 wherein the processor enables switching functionality in an optical domain.

23. An apparatus comprising:
an input port to receive at least one of optical and electrical signals;
an output port to send at least one of optical and electrical signals;
a linecard coupled with the input and output ports; and
a processing means on the linecard to enable processing local to the line card.

24. The linecard of claim 23 further comprising at least one of an error correction and a digital wrapping integrated circuit.

25. The linecard of claim 24 wherein the error correction integrated circuit is a Forward Error Correction (FEC) integrated circuit.

26. A system comprising:
a first switch including a first linecard;
a second switch including a second linecard and connected to the first switch through a network; and
a processor on the first linecard to configure the first linecard based upon information at least in part communicated through the network from the second linecard.

27. The system of claim 26 wherein the linecard configuration involves provisioning of a circuit through the network.

28. The system of claim 26 wherein the processor encapsulates data between a first network protocol to a second network protocol.

29. The system of claim 26 wherein the first network protocol is at least one of Synchronous Optical Network (SONET) and Synchronous Design Hierarchy.
